(19) United States
(12) Patent Application Publication
(10) Pub. No.: US 2009/0261393 A1
(43) Pub. Date: Oct. 22, 2009

(54) COMPOSITE TRANSFER GATE AND FABRICATION THEREOF

(75) Inventor: Jhy-Jyi Sze, Hsinchu City (TW)

Correspondence Address: J C PATENTS, 4 VENTURE, SUITE 250, IRVINE, CA, 92618, US

(73) Assignee: UNITED MICROELECTRONICS CORP., Hsinchu (TW)

(21) Appl. No.: 12/105,514

(22) Filed: Apr. 18, 2008

(51) Int. Cl. H01L 31/00; H01L 21/00

(52) U.S. Cl. 257/291; 438/57; 257/E31.001; 257/E21.001

(57) ABSTRACT

A composite transfer gate is described, which is disposed over a semiconductor substrate between an electron reservoir and a floating node in the semiconductor substrate. The composite transfer gate includes at least one N-type portion and a P-type portion that are arranged laterally.

### BACKGROUND OF THE INVENTION

1. Field of Invention

This invention relates to a semiconductor structure and fabrication thereof, and more particularly relates to a composite transfer gate disposed between an electron reservoir and a floating node and to a method of fabricating the same.

2. Description of Related Art

The combination of an electron reservoir, a floating node and a transfer gate between them is frequent seen in various kinds of signal sensors, for example, a CMOS image sensor (CIS). Each pixel of a CIS is usually disposed with four MOS transistors including the transfer transistor.

In a traditional CIS, a transfer gate is fully N-doped like the floating node, while an extra pinning region of P-type is formed under the transfer gate and in the electron reservoir to reduce the dark current, so that the full well capacity of photoelectrons is decreased lowering the S/N ratio of the sensor. It is difficult to make the dark current inhibition and image lag prevention both effective with a fully N-doped transfer gate.

Hence, some current CMOS image sensors adopt fully P-doped transfer gates, so that no extra pinning doped region is required and the full well capacity is not lowered. However, in such a case, the threshold voltage under a portion of the transfer gate near the floating node is greatly raised, so that the charge transfer process is retarded causing image lag and a charge injection issue is induced increasing the photodiode noise.

### SUMMARY OF THE INVENTION

Accordingly, this invention provides a composite transfer gate, which may be applied to a transfer transistor of an electronic image sensor to achieve a high full well capacity, dark current inhibition and image lag prevention simultaneously.

This invention also provides a method of fabricating an above composite transfer gate of this invention.

The composite transfer gate of this invention is disposed over a semiconductor substrate between an electron reservoir and a floating node in the substrate, including at least one N-type portion and a P-type portion that are arranged laterally.

In an embodiment, the composite transfer gate includes only one N-type portion located at an edge of the composite transfer gate facing the floating node.

In an embodiment, the composite transfer gate includes only one N-type portion, and the one N-type portion is at the middle of the P-type portion.

In an embodiment, the composite transfer gate includes at least two N-type portions that include one first N-type portion at an edge of the transfer gate facing the floating node, and at least one second N-type portion at the middle of the P-portion.

In an embodiment, the composite transfer gate includes at least two N-type portions at the middle of the P-type portion.

In an embodiment, the at least one N-type portion of the composite transfer gate has a lateral gradient in N-type dopant concentration, wherein the at least one N-type portion is preferably at an edge of the composite transfer gate facing the floating node.

Moreover, when the width of the composite transfer gate is more than 0.45 μm, the width ratio of the at least one N-type portion to the P-type portion is preferably less than ¼. When the width of the composite transfer gate is less than or equal to 0.45 μm, the above width ratio is preferably less than ⅓. The composite transfer gate may belong to an optical sensor that also includes the electron reservoir and the floating node, wherein the optical sensor may be a CMOS image sensor.

A method of fabricating a composite transfer gate of this invention is as follows. A P-type semiconductor layer is formed over the substrate and patterned to form a gate conductor. A mask layer exposing a portion of the gate conductor is formed over the substrate, and N-type ion implantation is done to convert the exposed portion of the gate conductor to an N-type portion, while the other portion thereof is a P-type portion.

In an embodiment of this invention, the exposed portion of the gate conductor is at an edge of the gate conductor facing the floating node. In such a case, it is possible that the mask layer also exposes a portion of the substrate at the side of the edge of the gate conductor and the N-type ion implantation also forms the floating node in the portion of the substrate. Another N-type ion implantation may be further performed to form at least one extra N-type potion at the middle of the P-type portion.

Moreover, when the width of the composite transfer gate is more than 0.45 μm, the width ratio of the N-type portion to the P-type portion is preferably less than ¼. When the width of the composite transfer gate is less than or equal to 0.45 μm, the width ratio of the N-type portion to the P-type portion is preferably less than ⅓.

Another method of fabricating a composite transfer gate of this invention is as follows. A doped semiconductor layer is formed over the substrate, including a P-type segment and an N-type segment arranged laterally and connected with each other. The semiconductor layer is patterned to form a gate conductor including a P-type portion previously as a portion of the P-segment and an N-type portion previously as a portion of the N-segment, wherein the N-type portion is arranged facing the floating node.

In an embodiment of the above method, an N-type ion implantation is further performed to form at least one extra N-type potion at the middle of the P-type portion.

As mentioned above, the composite transfer gate of this invention includes at least one N-type portion and a P-type portion that are arranged laterally. Hence, as compared with the conventional fully N-doped transfer gate, the dark current can be decreased by the P-type portion without formation of an extra pinning doped region so that dark current inhibition and a high full well capacity can be made simultaneously. As compared with the conventional fully P-doped transfer gate, the N-type portion, especially the one at an edge of the composite transfer gate facing the floating node, can lower the threshold voltage of the transfer transistor to prevent image lag.

In order to make the aforementioned and other objects, features and advantages of the present invention comprehensible, a preferred embodiment accompanied with figures is described in detail below.

### BRIEF DESCRIPTION OF THE DRAWINGS

FIG. 1 illustrates a local cross-sectional view of a CMOS image sensor unit that includes a composite transfer gate according to an embodiment of this invention.

FIGS. 2A-2E illustrate the composite transfer gates respectively according to five other embodiments of this invention.

FIGS. 3A-3D illustrate, in a cross-sectional view, a CMOS image sensor process utilizing a method of fabricating a composite transfer gate according to an embodiment of this invention.

FIGS. 4-6 illustrate the methods of fabricating a composite transfer gate respectively according to three other embodiments of this invention.

### DESCRIPTION OF EMBODIMENTS

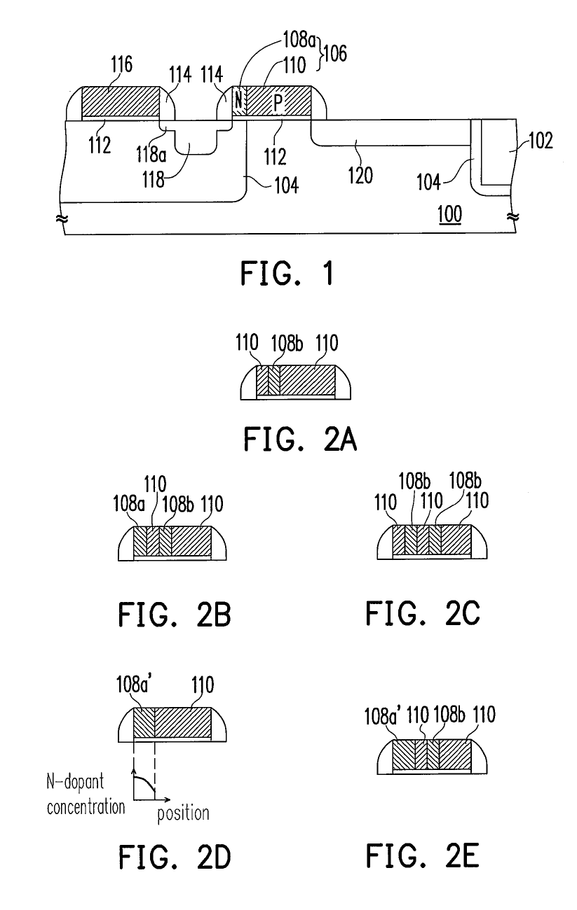

FIG. 1 illustrates a local cross-sectional view of a CMOS image sensor unit that includes a composite transfer gate according to an embodiment of this invention. The CMOS image sensor is a kind of optical sensor.

Referring to FIG. 1, in a semiconductor substrate 100, an isolation layer 102, a P-type field doped region 104 around the isolation layer 102, an N-doped region 118 as the floating node and an N-doped region 120 as the electron reservoir are formed. The composite transfer gate 106 is disposed over the substrate 100 between the floating node 118 and the electron reservoir 120, including a P-type portion 110 and an N-type portion 108a at an edge thereof facing the floating node 118 and being separated from the substrate 100 by a gate dielectric layer 112. The doped region 104 extends to under the N-type portion 108a. The width of the N-type portion 108a is preferably less than 0.15 μm. When the width of the composite transfer gate 106 is more than 0.45 μm, the width ratio of the N-type portion 108a to the P-type portion 110 is preferably less than ¼. When the width of the transfer gate 106 is less than or equal to 0.45 μm, the width ratio of the N-type portion 108a to the P-type portion 110 is preferably less than ⅓.

The sensor unit further includes a reset gate 116 disposed on the gate dielectric layer 112, which is opposite to the composite transfer gate 106 with the floating node 118 between them. Moreover, the doped region 118 as the floating node may have an extension regions 118a, and the sidewalls of the composite transfer gate 106 and the reset gate 116 are usually formed with spacers 114 thereon. The N-doped region 120 as the electron reservoir forms a photodiode as in combination with the substrate 100.

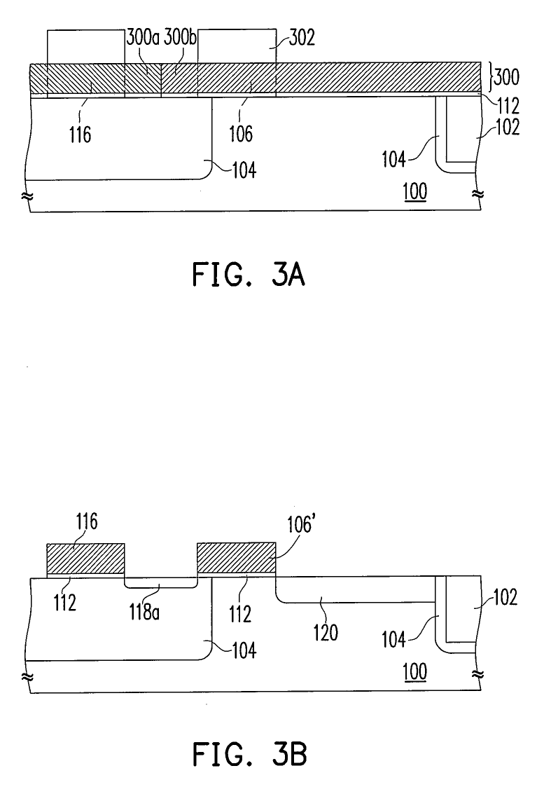

Though the composite transfer gate 106 in the above embodiment includes only one N-type potion 108a located at an edge of the composite transfer gate 106 facing the floating node 118, the number of N-type portion may alternatively be larger than one and the position of the same may be changed FIGS. 2A-2E illustrate the composite transfer gates respectively according to five other embodiments of this invention.

Referring to FIG. 2A, in this embodiment, there is still only one N-type potion 108b as in the above embodiment, but the N-type portion 108b is disposed at the middle of the P-type portion 110 dividing the P-type portion 110 into two pieces.

Referring to FIG. 2B, in this embodiment, there are two N-type potions including one N-type potion 108a at an edge of the composite transfer gate 106 facing the floating node 118, and one N-type potion 108b at the middle of the P-type potion 110 the divides the P-type portion 110 into two pieces.

Referring to FIG. 2C, there are also two N-type potions 108b in this embodiment, but the two N-type potions 108b are both at the middle of the P-type portion 110 dividing the P-type portion 110 into three pieces.

Referring to FIG. 2D, in this embodiment, there is only one N-type potion 108a′. The one N-type potion 108a′ is at an edge of the composite transfer gate 106 facing the floating node 118 and has a lateral gradient in the N-dopant concentration.

Referring to FIG. 2E, the composite transfer gate 106 in this embodiment not only includes the aforementioned edge N-type potion 108a′ but also includes one N-type portion 108b at the middle of the P-type portion 110 that divides the P-type portion 110 into two pieces. Moreover, such an N-type portion 108b at the middle of the P-type portion 110 may also have a lateral gradient in the N-dopant concentration.

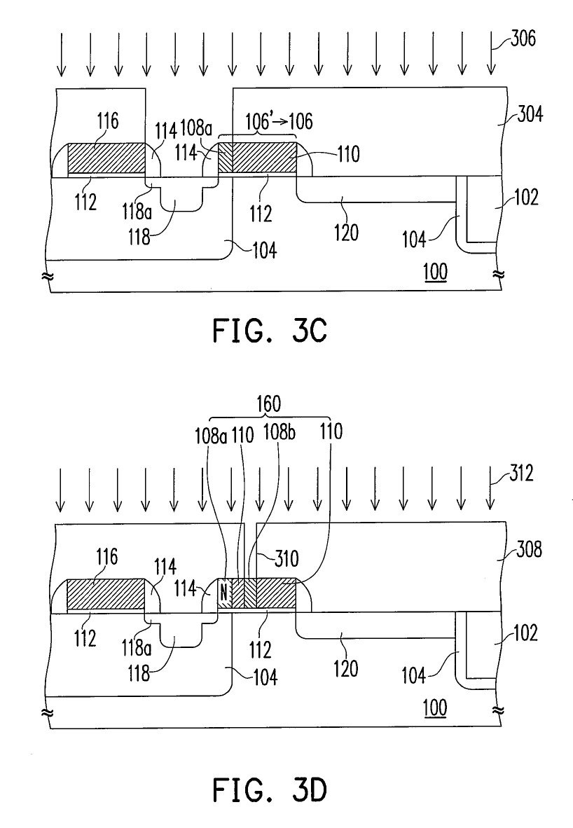

FIGS. 3A-3D illustrate, in a cross-sectional view, a CMOS image sensor process utilizing a method of fabricating a composite transfer gate according to an embodiment of this invention.

Referring to FIG. 3A, a semiconductor substrate 100, such as a lightly P-doped single-crystal silicon substrate, is provided, in which an isolation layer 102 and a P-type field doped region 104 therearound have been formed. A gate dielectric layer 112 and a doped semiconductor layer 300 like a doped poly-Si layer are formed on the substrate 100 in sequence. The semiconductor layer 300 includes an N-type segment 300a and a P-type segment 300b, which respectively include a portion for forming the reset gate 116 and a portion for forming the transfer gate 106. A patterned photoresist layer 302 is formed on the semiconductor layer 300, covering the portion of the N-type segment 300a for forming the reset gate 116 and the portion of the P-type segment 300b for forming the transfer gate 106. In addition, the doped semiconductor layer 300 may be formed by forming an undoped semiconductor layer and then performing N-type ion implantation and P-type ion implantation respectively to the corresponding areas.

Referring to FIG. 3B, after the N-doped reset gate 116 and the P-type transfer gate conductor 106′ are formed by etching with the photoresist layer 302 as a mask, the photoresist 302 is removed, and an N-type extension region 118a of the floating node and an N-doped region 120 as a part of the photodiode are formed in the substrate 100.

Referring to FIG. 3C, spacers 114 are formed on the sidewalls of the reset gate 116 and the transfer gate conductor 106′. Then, a patterned photoresist layer 304 is formed over the substrate 100, exposing the portion of the transfer gate conductor 106′ for forming the N-type portion 108a as well as the substrate 100 between the reset gate 116 and the transfer gate conductor 106′. An N-type ion implantation 306 is then performed, possibly in a dosage of 10¹³-10¹⁴/cm², preferably 5×10¹³/cm², to form the N-type portion 108a and also form the floating node 118 in the substrate 100 between the reset gate 116 and the transfer gate conductor 106′. The portion of the transfer gate conductor 106′ other than the N-type portion 108a is the above P-type portion 110.

Referring to FIG. 3D, after the N-type portion 108a is formed and the patterned photoresist layer 304 is removed, another N-type ion implantation 312 may be further performed to form at least one extra N-type portion 108b. The mask layer used in the N-type implantation 312 is a patterned photoresist layer 308 formed over the substrate 100 and having therein at least one opening 310 exposing the at least one portion of the P-type portion 110 for forming the at least one extra N-type portion 108b.

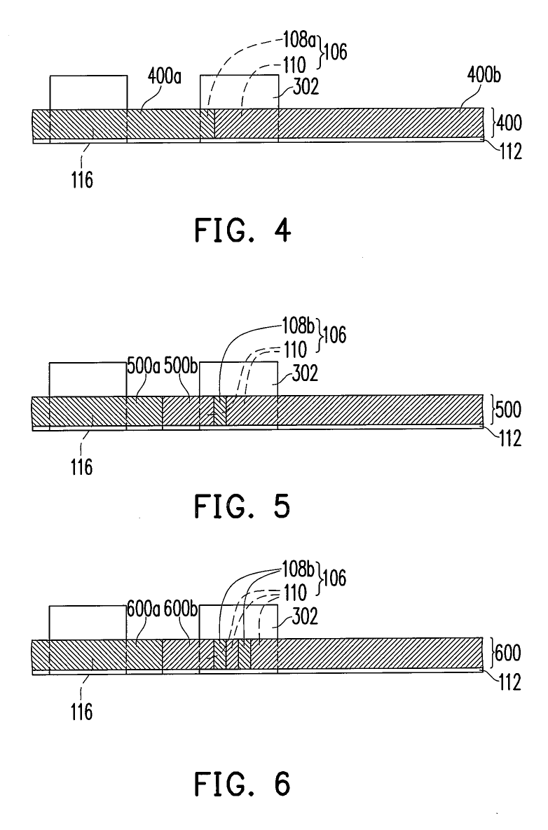

FIGS. 4-6 illustrate the methods of fabricating a composite transfer gate respectively according to three other embodiments of this invention.

Referring to FIG. 4, in this embodiment, a doped semiconductor layer 400 is formed on the gate dielectric layer 112, including an N-type segment 400a and a P-type segment 400b that are arranged laterally and connected with each other. The N-type segment 400a includes a portion for forming the reset gate 116 and an edge portion for forming the N-type portion 108a of the composite transfer gate 106. The P-type segment 400b includes a portion for forming the P-type portion 110 of the composite transfer gate 106. A patterned photoresist layer 302 for defining the reset gate 116 and the composite transfer gate 106 is then formed over the doped semiconductor layer 400, covering the potion of the N-type segment 400a for forming the reset gate 116 and the respective portions of the N-type segment 400a and the P-type segment 400b for forming the composite transfer gate 106. By etching the doped semiconductor layer 400 using the patterned photoresist layer 302 as a mask, a composite transfer gate 106 including an edge N-type portion 108a and a P-type portion 110 is formed.

Moreover, also referring to FIG. 3D, after the composite transfer gate 106 including an edge N-type portion 108a and a P-type portion 110 is formed as above, an N-type ion implantation may be performed, possibly in a dosage ranging from 10¹³/cm² to 10¹⁴/cm², preferably 5×10¹³/cm², to form at least one extra N-type potions 108b at the middle of the P-type portion 110 as in the precedent embodiment.

Referring to FIG. 5, the doped semiconductor layer 500 formed in this embodiment includes an N-type segment 500a and a P-type segment 500b. The N-type segment 500a includes a portion for forming the reset gate 116. The P-type segment 500b includes a portion for forming the composite transfer gate 106 as well as an N-type portion 108b in the middle of the portion for forming the P-type portion 110. Thus, after the doped semiconductor layer 500 is etched using the patterned photoresist layer 302 for defining the reset gate 116 and the composite transfer gate 106 as a mask, a composite transfer gate 106 including a P-type portion 110 and one N-type portion 108b in the middle of the P-type portion 110 is formed.

Referring to FIG. 6, the doped semiconductor layer 600 formed in this embodiment is different from the doped semiconductor layer 500 in the precedent embodiment only in that the P-type segment 600b includes two N-type potions 108b in the middle of the portion for forming the P-type portion 110 of the composite transfer gate 106. Thus, after the N-type segment 600a and the P-type segment 600b are etched using the patterned photoresist layer 302 for defining the reset gate 116 and the composite transfer gate 106 as a mask, a composite transfer gate 106 including a P-type portion 110 and two N-type portions 108b in the middle thereof is formed.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A composite transfer gate disposed over a semiconductor substrate between an electron reservoir and a floating node in the semiconductor substrate, comprising: at least one N-type portion and a P-type portion that are arranged laterally.

2. The composite transfer gate of claim 1, which comprises only one N-type portion located at an edge of the composite transfer gate facing the floating node.

3. The composite transfer gate of claim 1, which comprises only one N-type portion located at middle of the P-type portion.

4. The composite transfer gate of claim 1, which comprises at least two N-type portions that comprise one first N-type portion at an edge of the composite transfer gate facing the floating node, and at least one second N-type portion at middle of the P-type portion.

5. The composite transfer gate of claim 1, which comprises at least two N-type portions at middle of the P-type portion.

6. The composite transfer gate of claim 1, wherein the at least one N-type portion has a lateral gradient in N-type dopant concentration.

7. The composite transfer gate of claim 6, wherein the at least one N-type portion is at an edge of the composite transfer gate facing the floating node.

8. The composite transfer gate of claim 1, wherein a width of the composite transfer gate is more than 0.45 μm, and a width ratio of the at least one N-type portion to the P-type portion is less than ¼.

9. The composite transfer gate of claim 1, wherein a width of the composite transfer gate is less than or equal to 0.45 μm, and a width ratio of the at least one N-type portion to the P-type portion is less than ⅓.

10. The composite transfer gate of claim 1, which belongs to an optical sensor that also includes the electron reservoir and the floating node.

11. The composite transfer gate of claim 10, wherein the optical sensor is a CMOS image sensor.

12. A method of fabricating a composite transfer gate to be disposed between an electron reservoir and a floating node in a semiconductor substrate, comprising:
forming a P-type semiconductor layer over the semiconductor substrate;
patterning the P-type semiconductor layer to form a gate conductor;
forming over the substrate a mask layer that exposes a portion of the gate conductor; and
performing an N-type ion implantation to convert the exposed portion of the gate conductor to an N-type portion, while the other portion of the gate conductor is a P-type portion.

13. The method of claim 12, wherein the exposed portion of the gate conductor is at an edge of the gate conductor facing the floating node.

14. The method of claim 13, wherein the mask layer also exposes a portion of the substrate at a side of the edge of the gate conductor and the N-type ion implantation also forms the floating node in the portion of the substrate.

15. The method of claim 13, further comprising: performing another N-type ion implantation to form at least one extra N-type potion at middle of the P-type portion.

16. The method of claim 12, wherein a width of the composite transfer gate is more than 0.45 μm, and a width ratio of the N-type portion to the P-type portion is less than ¼.

17. The method of claim 12, wherein a width of the composite transfer gate is less than or equal to 0.45 μm, and a width ratio of the N-type portion to the P-type portion is less than ⅓.

18. A method of fabricating a composite transfer gate to be disposed between an electron reservoir and a floating node in a semiconductor substrate, comprising:
forming over the semiconductor substrate a doped semiconductor layer that comprises a P-type segment and an N-type segment that are arranged laterally and are connected with each other; and
patterning the doped semiconductor layer to form a gate conductor that comprises a P-type portion previously as a portion of the P-type segment and an N-type portion previously as a portion of the N-type segment, wherein the N-type portion is arranged facing the floating node.

19. The method of claim 18, further comprising: performing an N-type ion implantation to form at least one extra N-type potion at middle of the P-type portion.

20. The method of claim 18, wherein a width of the composite transfer gate is more than 0.45 μm, and a width ratio of the N-type portion to the P-type portion is less than ¼.
